(19) United States
(12) Patent Application Publication
(10) Pub. No.: US 2026/0040929 A1
(43) Pub. Date: Feb. 5, 2026

(54) SEMICONDUCTOR DEVICE ASSEMBLIES WITH MULTI-RETICLE DIES AND RETICLE-BRIDGING CONDUCTORS

(71) Applicant: Micron Technology, Inc., Boise, ID (US)

(72) Inventors: Bharat Bhushan, Singapore (SG); Kunal R. Parekh, Boise, ID (US); Akshay N. Singh, Boise, ID (US); Ameen D. Akel, Rancho Cordova, CA (US)

(21) Appl. No.: 19/281,012

(22) Filed: Jul. 25, 2025

Related U.S. Application Data
(60) Provisional application No. 63/677,955, filed on Jul. 31, 2024.

(51) Int. Cl. H01L 23/528; H01L 23/00; H01L 23/48; H01L 23/498; H10B 80/00

(52) U.S. Cl. CPC H01L 23/528; H01L 23/481; H01L 23/49811; H01L 24/08; H01L 24/80; H10B 80/00; H01L 2224/08145; H01L 2224/80895; H01L 2224/80896

(57) ABSTRACT

A semiconductor device assembly includes a multi-reticle semiconductor device including a continuous semiconductor substrate having a plurality of circuit regions separated from one another by a reticle-edge region absent any electrical conductors, a device connection layer formed over the multi-reticle semiconductor device and including a plurality of reticle-bridging conductors electrically coupling the plurality of circuit regions in the multi-reticle semiconductor device to one another, and a plurality of semiconductor devices disposed over the device connection layer and electrically coupled to the multi-reticle semiconductor device by vertical conductors extending through the device connection layer.

### CROSS-REFERENCE TO RELATED APPLICATION(S)

The present application claims priority to U.S. Provisional Patent Application No. 63/677,955, filed Jul. 31, 2024, the disclosure of which is incorporated herein by reference in its entirety.

### TECHNICAL FIELD

The present disclosure generally relates to semiconductor device assemblies, and more particularly relates to semiconductor device assemblies with multi-reticle dies and reticle-bridging conductors.

### BACKGROUND

Microelectronic devices generally have a die (i.e., a chip) that includes integrated circuitry with a high density of very small components. Typically, dies include an array of very small bond pads electrically coupled to the integrated circuitry. The bond pads are external electrical contacts through which the supply voltage, signals, etc., are transmitted to and from the integrated circuitry. After dies are formed, they are “packaged” to couple the bond pads to a larger array of electrical terminals that can be more easily coupled to the various power supply lines, signal lines, and ground lines. Conventional processes for packaging dies include electrically coupling the bond pads on the dies to an array of leads, ball pads, or other types of electrical terminals, and encapsulating the dies to protect them from environmental factors (e.g., moisture, particulates, static electricity, and physical impact).

### BRIEF DESCRIPTION OF THE DRAWINGS

FIGS. 1 through 4 are simplified schematic cross-sectional views of different stages of the manufacturing process of an example semiconductor device assembly in accordance with embodiments of the present technology.

FIG. 5 is a simplified schematic cross-sectional view of a semiconductor device assembly in accordance with embodiments of the present technology.

FIG. 6 is a simplified schematic partial plan view of a semiconductor device assembly in accordance with embodiments of the present technology.

FIG. 7 is a flow chart illustrating a method of making a semiconductor device assembly in accordance with an embodiment of the present technology.

FIG. 8 is a schematic view showing a system that includes a semiconductor device assembly configured in accordance with an embodiment of the present technology.

### DETAILED DESCRIPTION

The demand for greater performance from semiconductor devices appears to be insatiable. To increase the performance of a device, more features can be included in a device of given size by shrinking the feature dimensions through lithography improvements. As feature shrink nears theoretical limits, however, adding more features has driven an increase in the size (i.e., footprint) of semiconductor devices. With the footprint of semiconductor devices increasing up to the limit of lithographic reticle size (a limit which would require dramatic re-tooling of an entire industry to overcome), increasing the capability of semiconductor devices may be accomplished by integrating multiple reticle-limited semiconductor devices into a single assembly.

Reticle-limited semiconductor devices have a footprint greater than the size of a single reticle field (e.g., current EUV reticle sizes are limited to about 858 mm²) and include multiple reticle-sized circuit areas that, due to the limitations of accurately aligning two different reticle fields, may be spaced apart from one another by a region of un-patterned silicon substrate with no conductors or other circuit features therein (e.g., resembling two discrete dies in an un-singulated portion of a semiconductor wafer). Unlike two discrete dies in an un-singulated portion of semiconductor substrate, however, in a reticle-limited semiconductor device the multiple reticle-limited circuit areas may not be designed identically, however, and may include features intended to connected to each other across the un-patterned region of the substrate (e.g., by subsequent BEOL metallization or by connected to an interposer).

A challenge with these approaches to coupling the discrete circuit regions of a multi-reticle semiconductor device is the additional manufacturing cost, package size (e.g., from a dedicated interposer with solder bond line) and increased circuit path length (e.g. interposed between the multi-reticle semiconductor device and its host and/or between the multi-reticle semiconductor device and auxiliary devices integrated with it, such as memory). To solve these drawbacks and others, embodiments of the present disclosure provide semiconductor device assemblies with a prefabricated device connection layer that can be directly bonded, in a wafer-level operation, to a multi-reticle semiconductor device. The device connection layer can couple not only the discrete circuit regions of the multi-reticle semiconductor device to each other, but also the multi-reticle semiconductor device to other semiconductor devices in a heterogenous device assembly, such as memory.

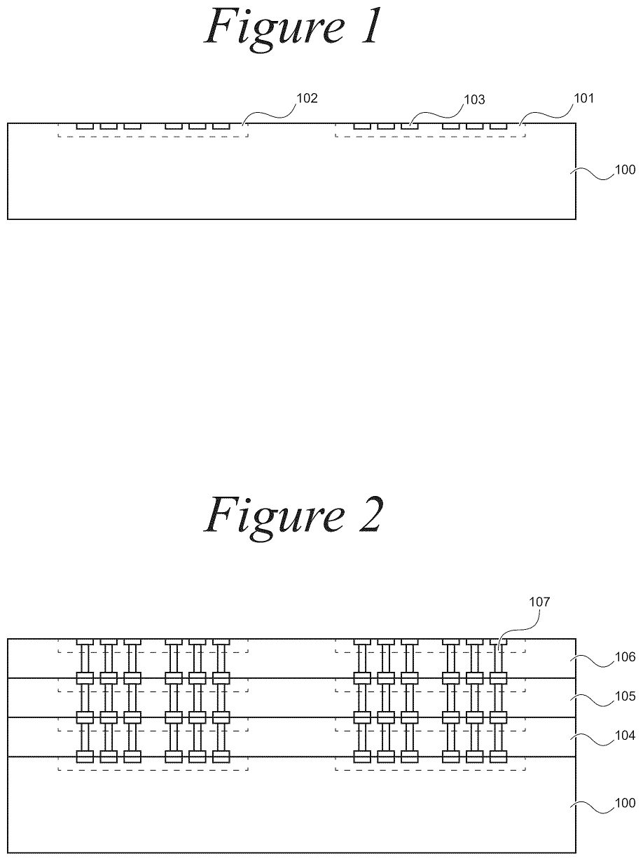

FIGS. 1 through 4 are simplified schematic cross-sectional views of different stages of the manufacturing process of an example semiconductor device assembly in accordance with embodiments of the present technology. Turning to FIG. 1, multiple semiconductor memory devices 101 & 102 are shown still in wafer format, disposed in an active region of wafer 100. Wafer 100 may also be referred to as top memory device wafer. Each memory device 101 or 102 is formed using a separate reticle shot. In one aspect, there are multiple memory devices within each representative memory device 101 and 102. For example, each memory device 101 or 102 may include at least 4, 6, 8, 10, or more unsingulated memory devices. In one aspect, the semiconductor memory devices 101 & 102 include a semiconductor substrate (e.g., silicon substrate) and multiple dielectric and metal layers that are part of the backend of the line layer (BEOL). The memory devices 101 & 102 include contact structures 103 for forming interconnects with additional devices by a wafer-level hybrid bonding process. In one aspect, the contact structures 103 are formed on the frontside of the memory devices 101 &102. These contact structures 103 may be formed using a damascene process. The contact structures 103 are connected to BEOL through via (e.g., tungsten or copper via) and probe pads (e.g., aluminum pads). As shown in FIG. 2, additional wafers 104-106 with additional semiconductor devices (outlined in dashed lines) can be hybrid-bonded to form stacks of devices coupled by the contact structures 103 and TSVs 107 vertically aligned therewith. The TSVs 107 may include either tungsten or copper material as conductive core. Furthermore, the TSVs 107 may be using a via last process or a via middle process. In one aspect, the additional wafers 104-106 are coupled to the wafer 100 by wafer-to-wafer (W2 W) bonding. Also, in one aspect, wafer 100 is bonded to wafer 104 through front-to-back (F2B) configuration, similar to wafer 104 bonding with wafer 105 and wafer 105 bonding with wafer 106. In one aspect, there may be 8 wafers bonded together. In another aspect, there may be more than 8 wafer bonded together such as at least be 12 wafers, 16 wafers, or 24 wafers. The hybrid bonding occurs between the contact structures 103 on the frontside of each wafer 100, 104-106 with backside corresponding contacts of the wafer it is being bonded. The backside contacts are formed using a damascene process after a TSV reveal process.

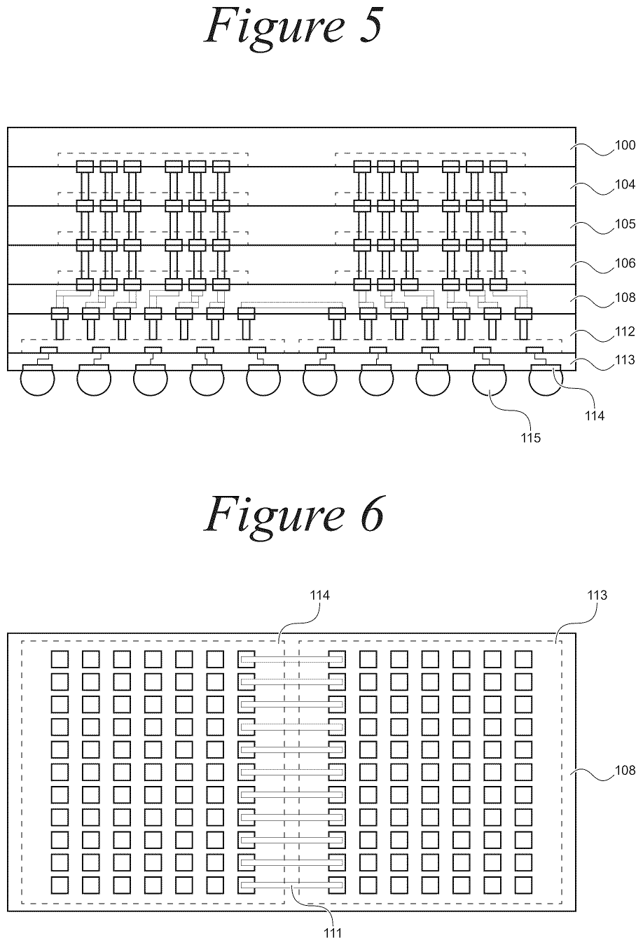

As is illustrated in FIG. 3, a device connection layer 108 can be formed over the stack of wafers 100 and 104-106 from FIG. 2. In one aspect, the device connection layer 108 may be a data proximity layer, which includes substrate, dielectric, and metallization layers. The device connection layer 108 may be connected to wafer 106 through wafer-to-wafer bonding and in the face-to-face (F2F) configuration. In one aspect, the device connection layer 108 may be used for connecting with memory devices 101 and 102 of respective wafers 100, 104, and 106. The device connection layer may also be used to manage the column of memory devices 101 and 102 and any repairs associated with TSVs. In one aspect, the via through the device connection layer 108 can have a different pitch than the via through the stacks of wafers 100, 104-106. The via going through device connection layer 108 may also have a different conductive composition compared to the via through the stacks of wafers 100, 104-106. The device connection layer can be formed like a redistribution layer, with back end of line (BEOL) metallization processes well known to those of skill in the art. For example, iteratively depositing and patterning dielectric material, and plating metal such as copper into the patterned openings in the dielectric material, permits the construction of metal contacts 110 both facing the exposed contacts 103 of wafer 106 and outwardly from the stack, as well as the conductive metal structures 109 that couple the contacts 110 on the wafer-facing (i.e., lower in the orientation of FIG. 3) side of the device connection layer 108 to contacts 110 on the outwardly-facing (i.e., upper in the orientation of FIG. 3) side of the device connection layer 108. In other embodiments, the device connection layer 108 may be formed with a silicon substrate within the device connection layer 108. In yet other embodiments, a redistribution may be formed on the backside of the device connection layer 108. The contacts 110 on the outwardly facing side of the device connection layer 108 include a subset that are not coupled to wafer-facing contacts 110 but are rather coupled by reticle-bridging conductors 111 (one pair is shown in the cross-sectional view of FIG. 3, additional pairs of the subset are illustrated in FIG. 6, below). The reticle-bridging conductors 111 can provide inter-region connectivity to a multi-reticle semiconductor device with multiple discrete circuit regions, as shown and described in greater detail below. In one aspect, the contacts 110 and reticle-bridging conductors 111 are located on the backside of the device connection layer 108. Further, contacts 110 may be formed using either single damascene process or dual damascene process.

Turning to FIG. 4, a wafer 112 including a multi-reticle semiconductor device with two discrete reticle-limited circuit regions 113 and 114 has been hybrid-bonded (i.e., with a dielectric-dielectric bond in regions without conductive contacts, and with a solder-free direct metal-metal bond in regions where TSVs 115 and contacts align with the contacts 110 of the device connection layer 108) to the device connection layer 108. In one aspect, the two discrete reticle-limited circuit regions 113 and 114 are graphical processing units (GPUs) or central processing units (CPUs). The wafer 112 is bonded to wafer 108 by way of wafer-on-wafer bonding, especially in back-to-front (B2F) configuration. Because of the reticle-limited size of the circuit regions 113 and 114, there are no conductors disposed within the region separating them, and prior to bonding the wafer 112 to the device connection layer 108, the circuit regions 113 and 114 are electrically isolated from one another. After the bonding operation however, reticle-bridging conductors 111 operably couple contacts from one circuit area 112 to the other 113, providing inter-region connectivity and permitting the multi-reticle semiconductor device to function as a single integrated device.

In the present example embodiment, wafer 100 has been illustrated as a “thick” wafer that has not been thinned, and which does not include TSVs, as a full-thickness wafer provides robust mechanical support for a stacking operation, as will be readily understood by one of skill in the art. Following the hybrid bonding of the multi-reticle semiconductor device wafer 112 to the wafer stack, the thick wafer 100 can be thinned to reduce the overall height of the eventual assembly, as illustrated in FIG. 4. In embodiments in which the height of the assembly is not critical, wafer 100 may be left thick to provide mechanical strength to the assembly. In other embodiments, however, rather than using a thick wafer to support the bonding operations illustrated in FIGS. 2 and 4, wafer 100 could be replaced with a thinned wafer (optionally including backside-exposed TSVs for connection out of the assembly) that is temporarily bonded to a carrier wafer that provides the desired mechanical support.

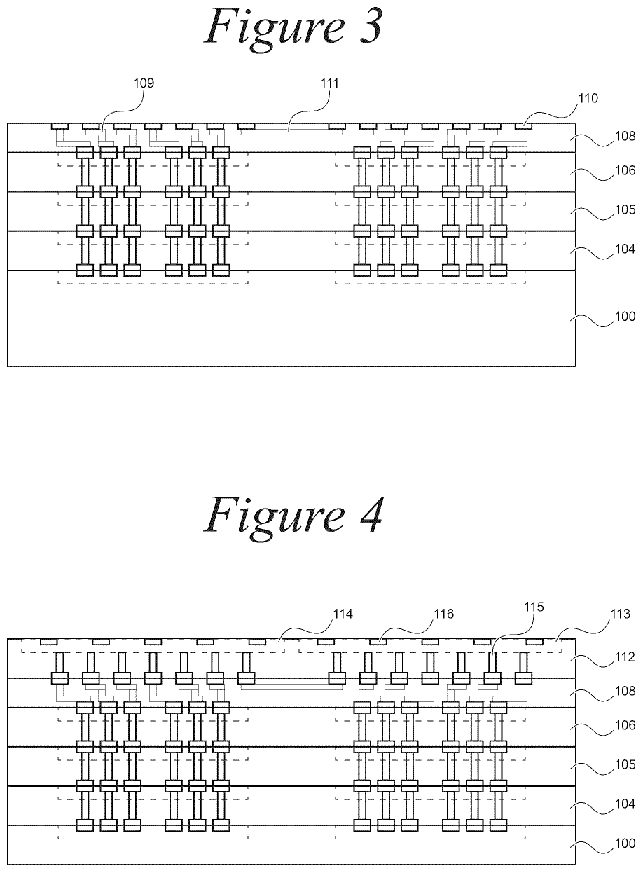

Turning to FIG. 5, a simplified schematic cross-sectional view of a semiconductor device assembly is illustrated after fabrication is complete in accordance with one embodiment of the present technology. A redistribution layer (RDL) 113 has been formed on the multi-reticle semiconductor device wafer 112, routing signals from the exposed contacts 116 of that wafer 112 to external contacts 114 of the assembly, on which solder balls 115 can be formed for connection to higher-level devices. The wafer stack can also be singulated at this point, such that the sidewalls illustrated in the Figure correspond to exterior surfaces of the singulated device. In one aspect, there may be more than 10,000 reticle-bridging conductors 111.

Turning to FIG. 6, a simplified schematic partial plan view of a semiconductor device assembly in accordance with embodiments of the present technology illustrates additional details of the device connection layer 108. As can be seen with reference to FIG. 6, device connection layer 108 includes multiple reticle-bridging conductors 111 arranged to electrically connect pair of contacts 110 associated with the discrete reticle-limited circuit areas 113 and 114 of the multi-reticle semiconductor device. Although in the present example embodiment, a multi-reticle semiconductor device is illustrated and described as including two discrete circuit areas 113 and 114, in other embodiments a multi-reticle semiconductor device can include more than two circuit areas, and the reticle bridging conductors 111 of the device connection layer 108 may couple contacts 110 to one another in a one-to-one, a one-to-many, and/or a many-to-many topology, as may be desirable for different multi-reticle semiconductor device designs.

Although in the foregoing example embodiments semiconductor device assemblies have been illustrated with two stacks of memory devices on a single multi-reticle semiconductor device, in other embodiments greater or lesser numbers of stacks may be provided over a multi-reticle semiconductor device. Moreover, memory devices so provided may comprise a single type of memory, (e.g., NAND or DRAM or PCM or SRAM or MRAM, etc.) or a mixture of different types of memory (e.g., NAND and/or DRAM and/or PCM and/or SRAM and/or MRAM, etc.). Still further, although stacks have been illustrated with four memory devices vertically aligned, in other embodiments different stack heights may be implemented with fewer (e.g., one, two, or three) or more (e.g., five, six, eight, ten, twelve, etc.) layers of memory devices. In this regard, the wafers 100, 104-106 including memory devices could be reconstituted wafers with known good dies to limit the exponential reduction in yield associated with taller stacks of devices from unsingulated wafers. Similarly, the multi-reticle semiconductor device wafer 112 could be a reconstituted or heterogenous device wafer.

Although in the foregoing example embodiments semiconductor device assemblies have been illustrated with wafers facing the same direction (e.g., with active surfaces bonded to inactive surfaces), in other embodiments a stack of wafers may be bonded with active surfaces facing in different directions (or, mutatis mutandis, all facing the opposite way than illustrated, with back surfaces facing the external package contacts).

Although in the foregoing example embodiments semiconductor device assemblies have been illustrated with wafers bonded exclusively with a hybrid bonding approach, in other embodiments other wafer bonding approaches (e.g., solder interconnects) could be used in the alternative or additionally.

Although in the foregoing example embodiments semiconductor device assemblies have been illustrated and described as being formed with two reticle-limited circuits, in other embodiments, assemblies can be formed with more than two such reticle limited circuits (e.g., an array of 3×1 such reticle-limited circuits, an array of 2×2 such circuits, or even arrays of 3×2, 4×2, 4×3, etc.). In such arrays, reticle bridging conductors may extend in at least two different directions (e.g. perpendicular to one another).

In accordance with one aspect of the present disclosure, the semiconductor devices illustrated in the assemblies of FIGS. 1-6 could be memory dies, such as dynamic random access memory (DRAM) dies, NOT-AND (NAND) memory dies, NOT-OR (NOR) memory dies, magnetic random access memory (MRAM) dies, phase change memory (PCM) dies, ferroelectric random access memory (FeRAM) dies, static random access memory (SRAM) dies, or the like. In an embodiment in which multiple dies are provided in a single assembly, the semiconductor devices could be memory dies of a same kind (e.g., both NAND, both DRAM, etc.) or memory dies of different kinds (e.g., one DRAM and one NAND, etc.). In accordance with another aspect of the present disclosure, the semiconductor dies of the assemblies illustrated and described above could be logic dies (e.g., controller dies, processor dies, accelerator dies, etc.), or a mix of logic and memory dies (e.g., a memory controller die and a memory die controlled thereby).

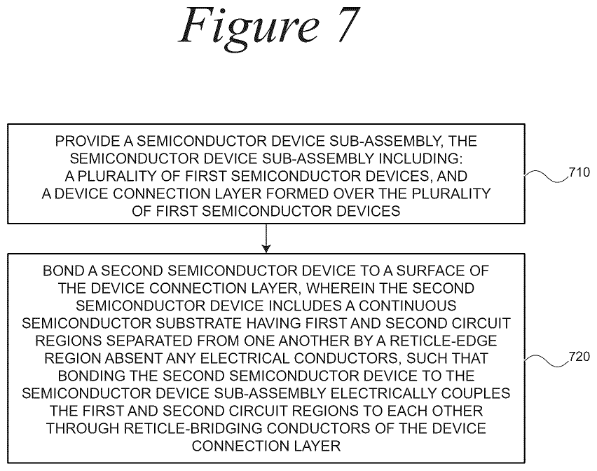

FIG. 7 is a flow chart illustrating a method of making a semiconductor device assembly. The method includes providing a semiconductor device sub-assembly, the semiconductor device sub-assembly including: a plurality of first semiconductor devices, and a device connection layer formed over the plurality of first semiconductor devices (box 710). The method further includes bonding a second semiconductor device to a surface of the device connection layer, wherein the second semiconductor device includes a continuous semiconductor substrate having first and second circuit regions separated from one another by a reticle-edge region absent any electrical conductors, such that bonding the second semiconductor device to the semiconductor device sub-assembly electrically couples the first and second circuit regions to each other through reticle-bridging conductors of the device connection layer (box 720).

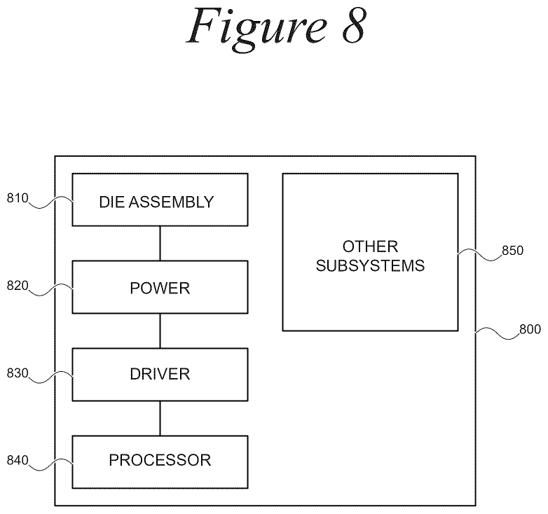

Any one of the semiconductor devices and semiconductor device assemblies described above with reference to FIGS. 1-6 can be incorporated into any of a myriad of larger and/or more complex systems, a representative example of which is system 800 shown schematically in FIG. 8. The system 800 can include a semiconductor device assembly (e.g., or a discrete semiconductor device) 802, a power source 804, a driver 806, a processor 808, and/or other subsystems or components 810. The semiconductor device assembly 802 can include features generally similar to those of the semiconductor devices described above with reference to FIGS. 1-6. The resulting system 800 can perform any of a wide variety of functions, such as memory storage, data processing, and/or other suitable functions. Accordingly, representative systems 800 can include, without limitation, hand-held devices (e.g., mobile phones, tablets, digital readers, and digital audio players), computers, vehicles, appliances, and other products. Components of the system 800 may be housed in a single unit or distributed over multiple, interconnected units (e.g., through a communications network). The components of the system 800 can also include remote devices and any of a wide variety of computer readable media.

Specific details of several embodiments of semiconductor devices, and associated systems and methods, are described above. A person skilled in the relevant art will recognize that suitable stages of the methods described herein can be performed at the wafer level or at the die level. Therefore, depending upon the context in which it is used, the term “substrate” can refer to a wafer-level substrate or to a singulated, die-level substrate. Furthermore, unless the context indicates otherwise, structures disclosed herein can be formed using conventional semiconductor-manufacturing techniques. Materials can be deposited, for example, using chemical vapor deposition, physical vapor deposition, atomic layer deposition, plating, electroless plating, spin coating, and/or other suitable techniques. Similarly, materials can be removed, for example, using plasma etching, wet etching, chemical-mechanical planarization, or other suitable techniques.

In other embodiments, the term “substrate” can refer to a package-level substrate upon which other semiconductor devices are carried, such as a printed circuit board (PCB), an interposer, or another semiconductor device.

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “vertical,” “lateral,” “upper,” “lower,” “above,” and “below” can refer to relative directions or positions of features in the semiconductor devices in view of the orientation shown in the Figures. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down, and left/right can be interchanged depending on the orientation.

It should be noted that the methods described above describe possible implementations, and that the operations and the steps may be rearranged or otherwise modified and that other implementations are possible. Furthermore, embodiments from two or more of the methods may be combined.

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

What is claimed is:

1. A semiconductor device assembly, comprising:
a multi-reticle semiconductor device including a continuous semiconductor substrate having a plurality of circuit regions separated from one another by a reticle-edge region absent any electrical conductors;
a device connection layer formed over the multi-reticle semiconductor device and including a plurality of reticle-bridging conductors electrically coupling the plurality of circuit regions in the multi-reticle semiconductor device to one another; and
a plurality of semiconductor devices disposed over the device connection layer and electrically coupled to the multi-reticle semiconductor device by vertical conductors extending through the device connection layer.

2. The semiconductor device assembly of claim 1, further a redistribution layer disposed under the multi-reticle semiconductor device opposite the device connection layer and electrically coupling the multi-reticle semiconductor device to a plurality of external package contacts.

3. The semiconductor device assembly of claim 1, wherein the plurality of circuit regions of the multi-reticle semiconductor device is disposed in an active layer of the multi-reticle semiconductor device facing away from the device connection layer.

4. The semiconductor device assembly of claim 1, wherein the plurality of reticle-bridging conductors extends horizontally over the reticle-edge region of the multi-reticle semiconductor device.

5. The semiconductor device assembly of claim 1, wherein:
the device connection layer includes a first bonding surface including a first planar dielectric surface and a first plurality of contact pads,
the multi-reticle semiconductor device includes a second bonding surface including a second planar dielectric surface and a second plurality of contact pads, and
the first bonding surface and the second bonding surface are hybrid-bonded to one another such that the first planar dielectric surface and the second planar dielectric surface are bonded by a dielectric-dielectric bond and such that each of the first plurality of contact pads is bonded to a corresponding one of the second plurality of contact pads by a metal-metal bond exclusive of any solder.

6. The semiconductor device assembly of claim 1, wherein the device connection layer further includes:
a first plurality of contact pads facing and electrically coupled to the multi-reticle semiconductor device,
a second plurality of contact pads facing and electrically coupled to the plurality of semiconductor devices, and
a plurality of metal conductive structures operably connecting contact pads of the second plurality to contact pads of the first plurality.

7. The semiconductor device assembly of claim 1, wherein at least one contact pad of the second plurality is not vertically aligned with any contact pad of the first plurality.

8. The semiconductor device assembly of claim 1, wherein every contact pad of the second plurality is vertically aligned with a corresponding contact pad of the first plurality.

9. The semiconductor device assembly of claim 1, wherein the plurality of semiconductor devices includes a plurality of stacks of semiconductor devices, each of the plurality of stacks directly coupled to the device connection layer.

10. A semiconductor device assembly, comprising:
a device connection layer including:
a first surface,
a first plurality of contact pads at the first surface
a second surface opposite the first surface,
a second plurality of contact pads at the second surface,
a first plurality of conductive structures electrically coupling each of the first plurality of contact pads to a corresponding contact pad of the second plurality of contact pads, and
a second plurality of conductive structures electrically coupling each of a first subset of the second plurality of contact pads to a corresponding contact pad of a second subset of the second plurality of contact pads; and
a plurality of semiconductor devices carried by the first surface of the device connection layer and electrically coupled to the first plurality of contact pads.

11. The semiconductor device assembly of claim 10, wherein at least one contact pad of the first plurality of contact pads is not vertically aligned with any contact pad of the second plurality of contact pads.

12. The semiconductor device assembly of claim 10, wherein every contact pad of the first plurality of contact pads is vertically aligned with a corresponding contact pad of the second plurality of contact pads.

13. The semiconductor device assembly of claim 10, wherein the plurality of semiconductor devices includes a plurality of stacks of semiconductor devices operably connected by through-silicon vias.

14. A method of making a semiconductor device assembly, comprising:
providing a semiconductor device sub-assembly, the semiconductor device sub-assembly including:
a plurality of first semiconductor devices, and
a device connection layer formed over the plurality of first semiconductor devices, the device connection layer including a first surface facing the plurality of first semiconductor devices a second surface opposite the first surface and having a second plurality of contact pads, wherein a first subset of the second plurality of contact pads is electrically connected to a second subset of the second plurality of contact pads by a plurality of reticle-bridging conductors; and
bonding a second semiconductor device to the second surface of the device connection layer of the semiconductor device sub-assembly, wherein the second semiconductor device includes a continuous semiconductor substrate having first and second circuit regions separated from one another by a reticle-edge region absent any electrical conductors, such that bonding the second semiconductor device to the semiconductor device sub-assembly electrically couples the first and second circuit regions to each other through the reticle-bridging conductors.

15. The method of claim 14, wherein the first surface of the device connection layer has a first plurality of contact pads operably coupled to the plurality of first semiconductor devices by a plurality of metal conductive structures.

16. The method of claim 15, wherein each of the first plurality of contact pads is electrically connected to a corresponding contact pad of the second plurality of contact pads, such that bonding the second semiconductor device to the semiconductor device sub-assembly electrically coupled the second semiconductor device to the plurality of first semiconductor devices through the plurality of metal conductive structures.

17. The method of claim 14, wherein bonding the second semiconductor device to the second surface of the device connection layer comprises forming a hybrid bond including dielectric-dielectric bonds and metal-metal bonds.

18. The method of claim 17, wherein the hybrid bond is exclusive of any solder material.

19. The method of claim 14, wherein providing the semiconductor device sub-assembly comprises hybrid bonding wafers including the plurality of first semiconductor devices into a vertical stack.

20. The method of claim 14, wherein bonding the second semiconductor device to the semiconductor device sub-assembly comprises a wafer-level bonding operation.
